(19) United States
(12) Patent Application Publication
(10) Pub. No.: US 2023/0411509 A1
(43) Pub. Date: Dec. 21, 2023

(54) GALLIUM NITRIDE HIGH ELECTRON MOBILITY TRANSISTOR

(71) Applicant: Excelliance MOS Corporation, Hsinchu County (TW)

(72) Inventors: Chu-Kuang Liu, Hsinchu County (TW); Hung-Kun Yang, Hsinchu County (TW)

(73) Assignee: Excelliance MOS Corporation, Hsinchu County (TW)

(21) Appl. No.: 18/459,452

(22) Filed: Sep. 1, 2023

Related U.S. Application Data
(62) Division of application No. 17/338,720, filed on Jun. 4, 2021.

(30) Foreign Application Priority Data
Apr. 8, 2021 (TW) 110112790

(51) Int. Cl. H01L 29/778; H01L 29/20

(52) U.S. Cl. CPC H01L 29/7787; H01L 29/2003

(57) ABSTRACT

A gallium nitride high electron mobility transistor including a substrate, a nucleation layer, a buffer layer, a channel layer, a barrier layer, a gate electrode, a source electrode, at least one first p-type gallium nitride island, a drain electrode, and a dielectric layer is provided. A second side of the gate electrode is opposite to a first side of the gate electrode. The first p-type gallium nitride island is disposed on the barrier layer on the second side of the gate electrode, and the drain electrode is also disposed on the barrier layer on the second side of the gate electrode and covers the first p-type gallium nitride island. The dielectric layer is disposed between the drain electrode and the first p-type gallium nitride island, so that the first p-type gallium nitride island is electrically floating.

### CROSS-REFERENCE TO RELATED APPLICATION

This application is a divisional application of and claims the priority benefit of U.S. patent application Ser. No. 17/338,720, filed on Jun. 4, 2021. The prior application Ser. No. 17/338,720 claims the priority benefit of Taiwan application serial no. 110112790, filed on Apr. 8, 2021. The entirety of each of the above-mentioned patent applications is hereby incorporated by reference herein and made a part of this specification.

### BACKGROUND

### Technical Field

The disclosure relates to a power transistor, and in particular to a high electron mobility transistor (HEMT).

### Description of Related Art

When a high electron mobility transistor is used, through a heterostructure between aluminum gallium nitride (AlGaN) and gallium nitride (GaN), a two dimensional electron gas (2DEG) with a high surface charge density and a high electron mobility is generated at a junction. Therefore, the high electron mobility transistor is suitable for an operation of high power, high frequency and high temperature. However, in a process of the high electron mobility transistor being instantaneously switched off, due to a surface defect, electrons tend to accumulate on a surface of an AlGaN barrier layer, and the 2DEG which serves as channel electrons is thus repelled. Therefore, a concentration of 2DEG decreases and a maximum drain electrode current decreases, resulting in a decrease in reliability because a switching performance of the transistor drops or the transistor fails.

### SUMMARY

The disclosure provides a high electron mobility transistor, which increases reliability of switching of the transistor.

A high electron mobility transistor of the disclosure includes: a substrate, a nucleation layer, a buffer layer, a channel layer, a barrier layer, a gate electrode, a source electrode, at least one first p-type gallium nitride island, a drain electrode, and a dielectric layer. The nucleation layer is disposed on the substrate. The buffer layer is disposed on the nucleation layer. The channel layer is disposed on the buffer layer. The barrier layer is disposed on the channel layer. The gate electrode is disposed on the barrier layer. The source electrode is disposed on the barrier layer on a first side of the gate electrode. The at least one first p-type gallium nitride island is disposed on the barrier layer on a second side of the gate electrode, and the second side of the gate electrode is opposite to the first side of the gate electrode. The drain electrode is disposed on the barrier layer on the second side of the gate electrode and covers the first p-type gallium nitride island. The dielectric layer is disposed between the drain electrode and the first p-type gallium nitride island, so that the first p-type gallium nitride island is electrically floating.

In an embodiment of the disclosure, the at least one first p-type gallium nitride island is multiple first p-type gallium nitride islands, and the first p-type gallium nitride islands are arranged along an extension direction of the drain electrode.

In an embodiment of the disclosure, the dielectric layer extends to be disposed between the drain electrode and the barrier layer, and the dielectric layer has multiple contact openings, so that the drain electrode contacts the barrier layer through the contact openings.

In an embodiment of the disclosure, the gate electrode includes a gate electrode metal layer and a p-type gallium nitride layer disposed between the barrier layer and the gate electrode metal layer.

Based on the above, in the disclosure, disposing at least one first p-type gallium nitride island generates an effect like a floating ring, and the first p-type gallium nitride island forms one or more electron holes to recombine redundant electrons on the barrier layer, so as to avoid the concentration of the two dimensional electron gas (2DEG) from being affected, thereby providing a high electron mobility transistor with good reliability.

To further describe the features and advantages of the disclosure, embodiments accompanied with drawings are described below in details.

### BRIEF DESCRIPTION OF THE DRAWINGS

FIG. 1 is a schematic top view of a high electron mobility transistor according to the first embodiment of the disclosure.

FIG. 2 is a schematic cross-sectional view of a section line A-A′ of FIG. 1.

FIG. 3 is a schematic top view of a high electron mobility transistor according to the second embodiment of the disclosure.

FIG. 4 is a schematic top view of a high electron mobility transistor according to the third embodiment of the disclosure.

FIG. 5 is a schematic top view of a high electron mobility transistor according to the fourth embodiment of the disclosure.

FIG. 6 is a schematic cross-sectional view of a section line II′ of FIG. 5.

FIG. 7 is a schematic cross-sectional view of a section line II-II′ of FIG. 5.

FIG. 8 is a schematic top view of a high electron mobility transistor according to the fifth embodiment of the disclosure.

### DESCRIPTION OF THE EMBODIMENTS

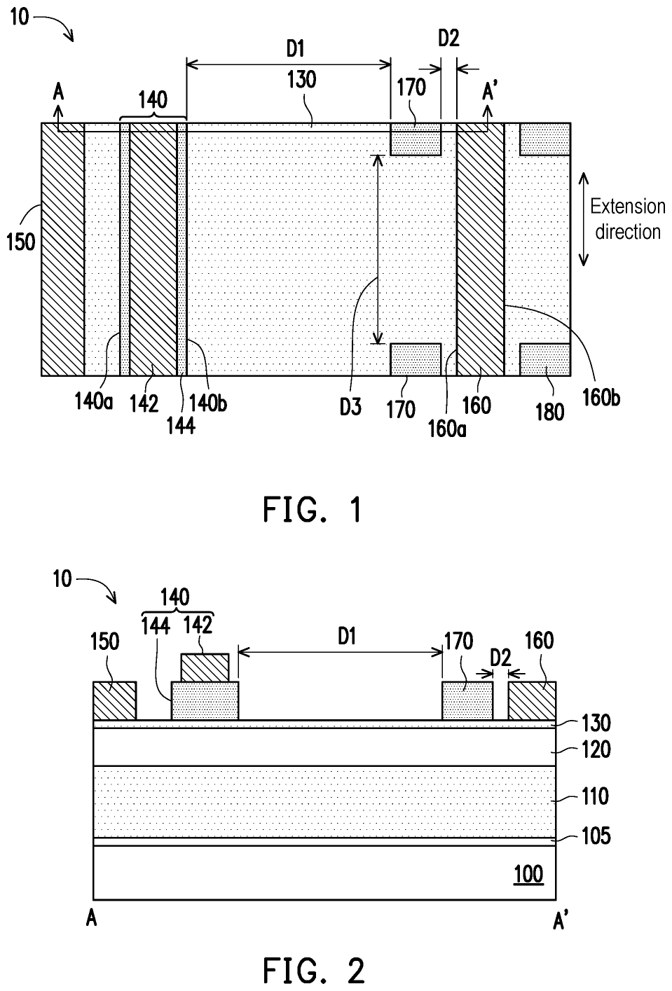

FIG. 1 is a schematic top view of a high electron mobility transistor according to the first embodiment of the disclosure. FIG. 2 is a schematic cross-sectional view of a section line A-A′ of FIG. 1.

First, referring to FIGS. 1 and 2, a high electron mobility transistor 10 includes: a substrate 100, a nucleation layer 105, a buffer layer 110, a channel layer 120, a barrier layer 130, a gate electrode 140, a source electrode 150, a drain electrode 160, and a plurality of first p-type gallium nitride islands 170. The nucleation layer 105 is disposed on the substrate 100. The buffer layer 110 is disposed on the nucleation layer 105. The channel layer 120 is disposed on the buffer layer 110. The barrier layer 130 is disposed on the channel layer 120. The gate electrode 140 is disposed on the barrier layer 130. The source electrode 150 is disposed on the barrier layer 130 on a first side 140a of the gate electrode 140. The drain electrode 160 is disposed on the barrier layer 130 on a second side 140b of the gate electrode 140. The first p-type gallium nitride islands 170 are respectively disposed between a first side 160a of the drain electrode 160 and the second side 140b of the gate electrode 140, and the first p-type gallium nitride islands 170 are electrically floating. The drain electrode 160 has an extension direction, and the first p-type gallium nitride islands 170 are arranged along the extension direction of the drain electrode 160.

Each of the first p-type gallium nitride islands 170 and the gate electrode 140 have a spacing D1. Each of the first p-type gallium nitride islands 170 and the drain electrode 160 have a spacing D2. The first p-type gallium nitride islands 170 have a spacing D3 between each other in the extension direction of the drain electrode 160. A location of the first p-type gallium nitride islands 170 are not limited and may be close to the drain electrode 160, that is, the spacing D1 between each of the first p-type gallium nitride islands 170 and the gate electrode 140 is greater than the spacing D2 between each of the first p-type gallium nitride islands 170 and drain electrode 160. The spacing D3 between the first p-type gallium nitride islands 170 arranged in a same row along the extension direction of the drain electrode 160 is not limited.

A second side 160b of the drain electrode 160 is opposite to the first side 160a of the drain electrode 160. On the second side 160b of the drain electrode 160, a plurality of second p-type gallium nitride islands 180 may be disposed, and the second p-type gallium nitride islands 180 are electrically floating, just like how the first p-type gallium nitride islands 170 are disposed.

Referring to FIG. 2, a material of the substrate 100 of the high electron mobility transistor may include, for example, sapphire, SiC, ZnO, Si, and Ga₂O₃; a material of the buffer layer 110 and the channel layer 120 may include undoped gallium nitride (GaN); a material of the barrier layer 130 may include undoped aluminum gallium nitride (AlGaN) (AlxGa1−xN, x=0.2˜1), but the disclosure is not limited thereto. The disposition of the buffer layer 110 may solve the problem of lattice mismatch between the substrate 100 and the channel layer 120.

A material of the source electrode 150 and the drain electrode 160 may be a suitable metal material, such as gold, titanium, titanium nitride, aluminum, or an alloy of the metals as described above. The gate electrode 140 may include a gate electrode metal layer 142 and a p-type gallium nitride layer 144 between the barrier layer 130 and the gate electrode metal layer 142. A material of the gate electrode metal layer 142 is, for example, nickel, platinum, tantalum nitride, titanium nitride, tungsten, or an alloy of the metals as described above, and the gate electrode metal layer 142 may be other suitable conductive materials, too. A material of the p-type gallium nitride layer 144 and the first p-type gallium nitride islands 170 are, for example, GaN doped with a dopant, and may be GaN doped with magnesium, but the disclosure is not limited thereto. The first p-type gallium nitride islands 170 are not electrically connected to the gate electrode 140 or the drain electrode 160, but are electrically independent of the gate electrode 140 or the drain electrode 160. Therefore, an effect such as a floating ring may be formed, and a potential of the first p-type gallium nitride islands 170 is between a potential of the gate electrode 140 and a potential of the drain electrode 160. When the elements as described above are turned on, the first p-type gallium nitride islands 170 inject one or more electron holes into the barrier layer 130.

An example of manufacturing the high electron mobility transistor 10 of the first embodiment is as follows. After the buffer layer 110, the channel layer 120, and the barrier layer 130 are sequentially formed on the substrate 100, the p-type gallium nitride layer 144 and the first p-type gallium nitride islands 170 are formed on the barrier layer 130 at the same time, and then the source electrode 150, the gate electrode metal layer 142, and the drain electrode 160 are formed. The layers as described above are formed by, for example, a chemical vapor deposition method, a physical vapor deposition method, or other appropriate formation methods, and the method is combined with a photolithographic etching process to manufacture each electrode and pattern.

In the high electron mobility transistor 10 of this embodiment, since disposing the first p-type gallium nitride islands 170 between the drain electrode 160 and the gate electrode 140 generates an effect like a floating ring, the first p-type gallium nitride islands 170 may form one or more electron holes to recombine redundant electrons on the barrier layer 130 so as to avoid the concentration of the two dimensional electron gas from being affected, thereby providing a high electron mobility transistor with good reliability.

The second p-type gallium nitride islands 180 have the same function as the first p-type gallium nitride islands 170. When the second side 160b of the drain electrode 160 of this embodiment is disposed with a gate electrode (not shown), too, the second p-type gallium nitride islands 180 may recombine the redundant electrons that appear on the surface of the barrier layer 130 during switching of the high electron mobility transistor 10, too, thereby providing a high electron mobility transistor with good reliability.

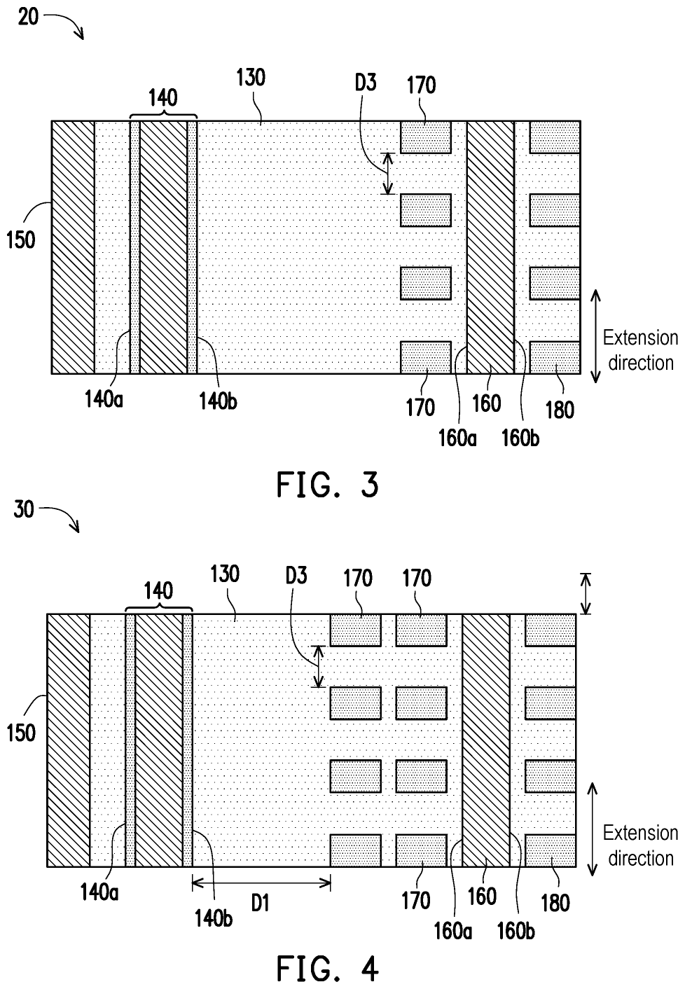

FIG. 3 is a schematic top view of a high electron mobility transistor according to the second embodiment of the disclosure. Same element symbols refer to same or like components in the first and second embodiments, and relevant descriptions in the first embodiment may be referred to for content of same or like components, which will not be repeated herein.

Referring to FIG. 3, four first p-type gallium nitride islands 170 are disposed on the high electron mobility transistor 20 in the extension direction of the drain electrode 160, so that the spacing D3 between the first p-type gallium nitride islands 170 is smaller than that of the first embodiment, and the spacing D3 between every two of the first p-type gallium nitride islands 170 may be the same or different, and the spacing D3 may be disposed to be the same so as to increase the ability of recombining the redundant electrons on the surface of the barrier layer 130.

FIG. 4 is a schematic top view of a high electron mobility transistor according to the third embodiment of the disclosure. Same element symbols refer to same or like components in the first and third embodiments, and relevant descriptions in the first embodiment may be referred to for content of same or like components, which will not be repeated herein.

Referring to FIG. 4, the difference between this embodiment and the first embodiment is that in this embodiment, there are two rows of the first p-type gallium nitride islands 170 between the first side 160a of the drain electrode 160 and the second side 140b of the gate electrode 140. The spacing D1 refers to a closest distance between the first p-type gallium nitride islands 170 and the gate electrode 140, so the spacing D1 between the first p-type gallium nitride islands 170 and the gate electrode 140 of this embodiment is smaller than that of the first embodiment. The spacing D3 between the first p-type gallium nitride islands 170 is smaller than that of the first embodiment, too, so as to increase the ability of recombining the redundant electrons on the surface of the barrier layer 130. The spacing D3 between the first p-type gallium nitride islands 170 may be the same or different, and the spacing D3 may be disposed to be the same.

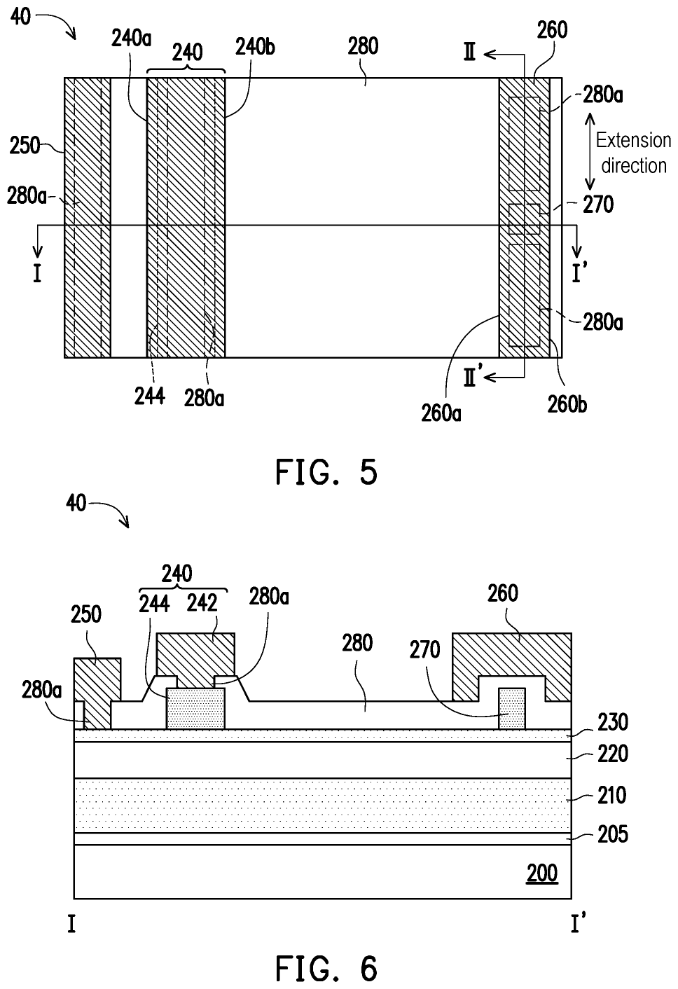

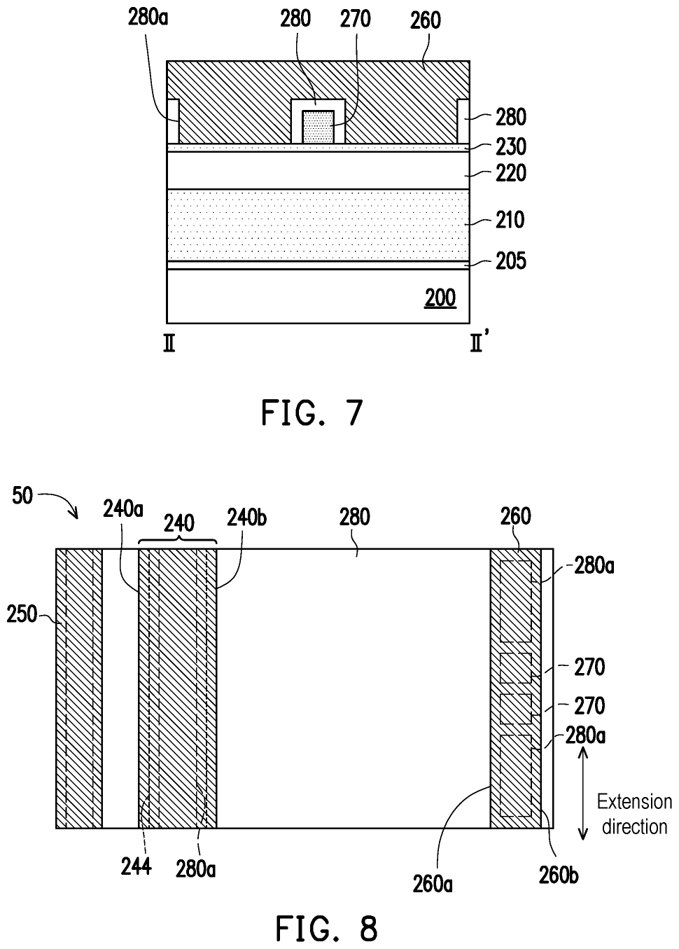

FIG. 5 is a schematic top view of a high electron mobility transistor according to the fourth embodiment of the disclosure. FIG. 6 is a schematic cross-sectional view of a section line II′ of FIG. 5. FIG. 7 is a schematic cross-sectional view of a section line II-II′ of FIG. 5.

Referring to FIGS. 5 to 7, a high electron mobility transistor 40 includes: a substrate 200, a nucleation layer 205, a buffer layer 210, a channel layer 220, a barrier layer 230, a gate electrode 240, a source electrode 250, a drain electrode 260, first p-type gallium nitride islands 270, and a dielectric layer 280. The nucleation layer 205 is disposed on the substrate 200. The buffer layer 210 is disposed on the nucleation layer 205. The channel layer 220 is disposed on the buffer layer 210. The barrier layer 230 is disposed on the channel layer 220. The gate electrode 240 is disposed on the barrier layer 230. The source electrode 250 is disposed on the barrier layer 230 on a first side 240a of the gate electrode 240. The first p-type gallium nitride islands 270 are disposed on the barrier layer 230 of a second side 240b of the gate electrode 240, and the second side 240b of the gate electrode 240 is opposite to the first side 240a of the gate electrode 240. That is, the first p-type gallium nitride islands 270 are disposed between the first side 260a and the second side 260b of the drain electrode 260. The number of first p-type gallium nitride islands 270 is not limited, and there may be one or more first p-type gallium nitride islands 270. The first p-type gallium nitride islands 270 are arranged along an extension direction of the drain electrode 260. The drain electrode 260 is disposed on the barrier layer 230 on the second side 240b of the gate electrode 240 and covers the first p-type gallium nitride islands 270.

The dielectric layer 280 is between the drain electrode 260 and the first p-type gallium nitride islands 270, so that the first p-type gallium nitride islands 270 are electrically floating. The dielectric layer 280 may extend to be disposed between the drain electrode 260 and the barrier layer 230, and the dielectric layer 280 has a plurality of contact openings 280a, so that the drain electrode 260 contacts the barrier layer 230 through the contact openings 280a. A material of the dielectric layer 280 is not limited, and may be a commonly used dielectric material. The first p-type gallium nitride islands 270 are not electrically connected to the gate electrode 240 or the drain electrode 260, but are electrically independent of the gate electrode 240 or the drain electrode 260. Therefore, disposing the floating first p-type gallium nitride islands 270 may generate an effect like a floating ring, and may form one or more electron holes to recombine redundant electrons on the barrier layer 230 so as to avoid the concentration of the two dimensional electron gas (2DEG) from being affected, thereby providing a high electron mobility transistor with good reliability.

An example of manufacturing the high electron mobility transistor 40 of the fourth embodiment is as follows. After the nucleation layer 205, the buffer layer 210, the channel layer 220, and the barrier layer 230 are sequentially formed on the substrate 200, a p-type gallium nitride layer 244 and the first p-type gallium nitride islands 270 are formed on the barrier layer 230, and then one dielectric layer 280 is deposited to cover the structure and film layers as described above. Next, a process, for example, photolithographic etching, is used to form the contact windows 280a in the dielectric layer 280 where a gate electrode, a source electrode, and a drain electrode are determined to be formed, and then the contact windows 280a are filled with a metal or an alloy to form the source electrode 250, the gate electrode metal layer 242, the drain electrode 260, and the first p-type gallium nitride islands 270. Materials and formation methods of the substrate 200, the buffer layer 210, the channel layer 220, the barrier layer 230, the gate electrode 240, the source electrode 250, the first p-type gallium nitride islands 270, and the drain electrode 260 are similar to those in the first embodiment, and will not be repeated herein. A formation method of the dielectric layer 280 is, for example, a chemical vapor deposition method or a spin coating technology.

FIG. 8 is a schematic top view of a high electron mobility transistor according to the fifth embodiment of the disclosure. Same element symbols refer to same or like components in the fifth and fourth embodiments, and relevant descriptions in the fourth embodiment may be referred to for content of same or like components, which will not be repeated herein.

Referring to FIGS. 8, the difference between this embodiment and the fourth embodiment is that in this embodiment, the number of first p-type gallium nitride islands 270 is increased. Therefore, an effect like a floating ring is generated, and the first p-type gallium nitride islands 270 can recombine redundant electrons on a surface of a high electron mobility transistor 50, so as to avoid the concentration of the two dimensional electron gas from being affected, thereby providing the high electron mobility transistor 50 with good reliability.

In summary, in the disclosure, the p-type gallium nitride islands disposed between the gate electrode and the drain electrode, or the p-type gallium nitride islands disposed below the drain electrode recombine the redundant electrons on the surface of the high electron mobility transistor so as to avoid the concentration of the two dimensional electron gas (2DEG) from being affected, thereby providing a high electron mobility transistor with good reliability.

Although the disclosure has been disclosed in the above by way of embodiments, the embodiments are not intended to limit the disclosure. Those with ordinary knowledge in the technical field can make various changes and modifications without departing from the spirit and scope of the disclosure. Therefore, the scope of protection of the disclosure is defined by the scope of the appended claims.

What is claimed is:

1. A high electron mobility transistor, comprising:
a substrate;
a nucleation layer, disposed on the substrate;
a buffer layer, disposed on the nucleation layer;
a channel layer, disposed on the buffer layer;
a barrier layer, disposed on the channel layer;
a gate electrode, disposed on the barrier layer;
a source electrode, disposed on the barrier layer on a first side of the gate electrode;
at least one first p-type gallium nitride island, disposed on the barrier layer on a second side of the gate electrode, wherein the second side of the gate electrode is opposite to the first side of the gate electrode;
a drain electrode, disposed on the barrier layer on the second side of the gate electrode, covering the at least one first p-type gallium nitride island; and
a dielectric layer, disposed between the drain electrode and the at least one first p-type gallium nitride island, so that the at least one first p-type gallium nitride island is electrically floating.

2. The high electron mobility transistor according to claim 1, wherein the at least one first p-type gallium nitride island is a plurality of first p-type gallium nitride islands, and the first p-type gallium nitride islands are arranged along an extension direction of the drain electrode.

3. The high electron mobility transistor according to claim 1, wherein the dielectric layer extends to be disposed between the drain electrode and the barrier layer, and the dielectric layer has a plurality of contact openings, so that the drain electrode contacts the barrier layer through the contact openings.

4. The high electron mobility transistor according to claim 1, wherein the gate electrode comprises a gate electrode metal layer and a p-type gallium nitride layer disposed between the barrier layer and the gate electrode metal layer.
